(19) United States
(12) Patent Application Publication
(10) Pub. No.: US 2010/0045312 A1
(43) Pub. Date: Feb. 25, 2010

(54) Shaped-Seal, Sealing Arrangement and Process Sensor Having Such a Sealing Arrangement

(75) Inventors: Torsten Pechstein, Radebeul (DE); Robert Scholz, Luttewitz/Dobeln (DE)

Correspondence Address: BACON & THOMAS, PLLC, 625 SLATERS LANE, FOURTH FLOOR, ALEXANDRIA, VA, 22314-1176, US

(73) Assignee: Endress + Hauser Conducta Gesellschaft fur Mess- und Regeltechnik mbH + Co. KG, Gerlingen (DE)

(21) Appl. No.: 12/227,627

(22) PCT Filed: May 22, 2007
(86) PCT No.: PCT/EP2007/054919

§ 371 Date: Oct. 16, 2009

(30) Foreign Application Priority Data
May 24, 2006 (DE) 10 2006 024 905.4

(51) Int. Cl. F16J 15/16; G01R 27/08; G01M 19/00

(52) U.S. Cl. 324/722; 277/500; 73/865.8

(57) ABSTRACT

A shaped-seal for sealing an annular gap between an outer peripheral wall and an inner peripheral wall against a medium, including: an elastic, radially clampable, annular sealing element having an annular, radially outer, sealing surface for contacting the outer peripheral wall, an annular, radially inner, sealing surface for contacting the inner peripheral wall, an annular, media-side, ceiling surface, which extends between the radially outer, sealing surface and the radially inner, sealing surface, an annular base surface, which extends on the side facing away from the ceiling surface, between the outer sealing surface and the inner sealing surface, and at least one annular cavity in the base surface for accommodating an anchoring ring, wherein the cavity has at least one undercut.

The present invention relates to a shaped-seal, a sealing arrangement and a process sensor having such a sealing arrangement.

Various process sensors include at least sectionally cylindrical, coaxially arranged, outer and inner components, between which an annular gap or an annular chamber of a media-containing space is to be sealed. In the simplest case, the annular gap can be closed with a sealing ring clamped between the cylindrical components. If, however, the annular gap exceeds a certain width, then an O-ring is no longer practical, and, instead, for example, a shape-retaining seal support body can be arranged between the inner and outer components; in such case, the seal support body has an inner seal seat and an outer seal seat, with, in each case, a sealing ring being arranged in the respective seal seats for sealing the seal support body relative to the outer and inner components. Such a sealing arrangement is used, for example, in the case of the conductivity sensor CLS16 of the assignee. Although this sealing arrangement basically fulfills its purpose, it has, nevertheless, its limits, for, first of all, sealing function at four peripheral seams has to be assured, second, gap formation along these four sealing seams has to be prevented, third, attention must be paid, that the sealing rings are also not sucked out of their seal seats in the case of media-side, low pressure, thus leading to leakage, and fourth, the material of the sealing support body must be compatible with the process medium. These constraints lead to complex designs and/or mounting steps.

It is, therefore, an object of the invention to provide an improved sealing arrangement and a shaped-seal for such a sealing arrangement.

The object is achieved, according to the invention, by the shaped-seal as defined in independent patent claim 1, the sealing arrangement as defined in independent patent claim 5 and the process sensor as defined in independent patent claim 10.

The shaped-seal of the invention involves the idea, on the one hand, of reducing to a minimum the number of sealing surfaces for process-side sealing of annular gaps, and, on the other hand, of separating the seal support body from the process medium by means of the shaped-seal. Finally, the seal can be optimized as regards special process conditions, such as e.g. low pressure. The disadvantages of the state of the art are removed therewith.

The shaped-seal of the invention for sealing an annular gap between an outer peripheral wall and an inner peripheral wall against a medium includes:

an elastic, radially clampable, annular sealing element having

an annular, radially outer, sealing surface for contacting the outer peripheral wall,

an annular, radially inner, sealing surface for contacting the inner peripheral wall,

an annular, media-side, ceiling surface extending between the radially outer, sealing surface and the radially inner, sealing surface,

an annular base surface extending on the side facing away from the ceiling surface, between the outer sealing surface and the inner sealing surface, and at least one annular cavity in the base surface for accommodating an anchoring ring, wherein the cavity has at least one undercut.

The sealing element has in the non-mounted state, in its equilibrium position, thus without the influence of external forces, preferably a cross section of approximately, for instance, rectangular, outer contour.

The height of the cross sectional contour amounts, for example, to not less than 40%, preferably not less than 55% and further preferably not less than 60% of the width of the cross sectional contour, with the height extending in the axial direction of the annular shaped-seal and the width in the radial direction.

The height of the cross sectional contour amounts furthermore, for example, to not more than 100%, preferably not more than 85% and further preferably not more than 70% of the width of the cross sectional contour.

The at least one cavity is, in an embodiment of the invention, to a first approximation, symmetrically arranged in the cross section of the sealing element.

The cavity has, in cross section, in the radial direction, for example, a maximum width of not more than 70%, preferably not more than 60% and further preferably not more than 54% of the width of the cross sectional contour of the sealing element.

The cavity has, in cross section, in the radial direction, for example, a maximum width of not less than 38%, preferably not less than 45% and further preferably not less than 48% of the width of the cross sectional contour of the sealing element.

For forming an undercut, the cavity has between the section of maximum width in the interior of the sealing element and the base surface a section of minimal width.

The minimum width amounts, for example, to not more than 45%, preferably not more than 38% and further preferably not more than 33% of the width of the cross sectional contour of the sealing element.

The minimum width amounts, furthermore, for example, to not less than 20%, preferably not less than 25% and further preferably not less than 28% of the width of the cross sectional contour of the sealing element.

For reducing stresses, especially stress concentrations, the contours of the cavity are rounded in cross section. Concave surfaces of the sealing element within the cavity have a minimum radius of curvature of, for example, not less than 5% and preferably not less than 8% of the width of the cross sectional contour of the sealing element.

Convex surfaces of the sealing element within the cavity have a minimum radius of curvature of, for example, not less than 10% and preferably not less than 15% of the width of the cross sectional contour of the sealing element.

The height of the cavity measured perpendicular to the base surface amounts, for example, to about 50% to 80%, preferably, for instance, 60% to 68%, of the height of the cross sectional contour of the sealing element.

In the interior of the cavity, the surface of the sealing element has a concave region, which transitions toward the opening in the base surface into a convex region. In the cross section, this transition is effected by a point of inflection or by a region with constant slope. The constant slope or the slope at the point of inflection amounts, for example, to not less than 30°, preferably not less than 38° and further preferably not less than 42°.

The constant slope or the slope at the point of inflection amounts, for example, to not more than 60°, preferably not more than 52° and further preferably not more than 48°.

The radially outer, sealing surface extends preferably parallel to the radially inner, sealing surface, when the shaped-seal is mounted on an anchoring ring and, in accordance with its purpose, radially clamped in an annular gap.

The sealing element comprises, preferably, an elastomer, especially a perfluoroelastomer, for example, EPDM or Kalrez perfluoroelastomer.

The sealing arrangement of the invention includes a shaped-seal of the invention as well as a seal support body of the invention having an annular base section and an anchoring ring arranged on an end face of the base section. The anchoring ring is dimensioned fittingly for the cavity, so that the shaped-seal achieves the desired sealing action, when the sealing element is mounted with the cavity on the anchoring ring and radially clamped.

The anchoring ring can have, for example, a mushroom-shaped, or bollard-shaped, cross section, with which it engages, in shape-interlocked manner, in the undercuts of the cavity of the sealing element.

The anchoring ring can be so dimensioned, that the cross section of the sealing element is widened, when the cavity is arranged about the anchoring ring. When, then, the shaped-seal, in accordance with its intended purpose, is radially clamped between an outer wall and an inner wall, this leads to a radial compressing and deforming acting on the sealing element from both the anchoring ring and the wall, i.e. the inner wall and the outer wall.

The radial compression amounts to, for example, about 10% to 25%.

In order to enable an optimal sealing action for positive, high pressure and for negative, low (vacuum) pressure applications, for example, the height of the anchoring ring, measured from the end face of the base section of the sealing support body, can be larger than the height of the cavity, so that the base surface of the sealing element does not sit, at equilibrium, on the end face of the base section of the sealing support body.

The anchoring ring can have, for example, a mushroom-shaped or bollard-shaped cross section, with which it engages shape-interlockedly in the undercuts of the cavity of the sealing element.

The seal support body comprises preferably a shape-retaining material, for example, a metal, a ceramic, or a synthetic material, or plastic, which, on occasion, can be glass-fiber reinforced. To the extent that insulating materials are desired, PEEK is currently preferred.

In order to lessen or eliminate excessive relative movement between the shaped-seal and the adjoining sealing surfaces of an inner wall or an outer wall, the seal support body can be fixedly connected with one or both of the walls.

In an embodiment of the invention, the seal support body includes in the base section an internal thread, into which, after the mounting of the shaped-seal on the anchoring ring, an external thread on the lateral surface of an inner, at least sectionally cylindrical, body is screwed, wherein a cylindrical lateral surface section forms the inner wall of the annular gap to be sealed, and wherein the shaped-seal is at least partially radially compressed by the inner wall.

The arrangement, including the shaped-seal mounted on the seal support body and the screwed-in, inner, at least sectionally cylindrical body, is then introduced into an outer, at least sectionally cylindrical body, wherein at least one cylindrical, lateral surface section forms the outer wall of the annular gap to be sealed.

In the outer, at least sectionally cylindrical body, a wall section is conically shaped, whereby the radially outer compression of the shaped-seal can be controllably achieved by the outer wall, when the shaped-seal mounted on the assembly is moved through the conical section. The final seal seat should, however, preferably have a cylindrical outer wall.

The sealing arrangement of the invention is especially suitable for sensors of process measurements technology, for example, for conductivity sensors, in the case of which a first metal electrode forms the inner wall of an annular chamber and a second, coaxially arranged electrode the outer wall of the annular chamber. Through the sealing arrangement, the two electrodes are electrically insulated from, and centered relative to, one another, and the annular chamber, into which the medium to be measured medium can penetrate, is limited to a defined axial end-section by the sealing arrangement.

The radially inner and outer, sealing surfaces adjoin, preferably gap-freely, the inner and outer walls of the annular chamber, which is formed between the inner and outer walls and limited axially by the shaped-seal. The ceiling surface extends preferably essentially planarly, or, at most, is only slightly curved, in order to prevent the occurrence of media-contacting dead spaces in the edge region. As a result, such a sealing arrangement can fulfill the requirements for hygienic applications.

The invention will now be explained in greater detail on the basis of an example of the invention illustrated in the appended drawing, the figures of which show as follows:

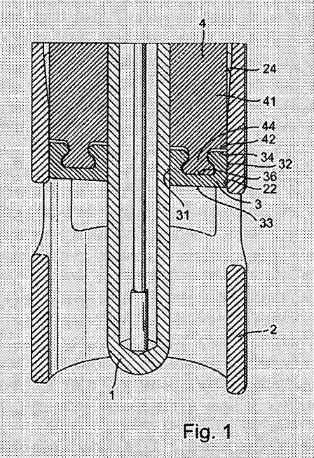

FIG. 1 a longitudinal section through a sensor head of a conductivity sensor of the invention, equipped with a sealing arrangement of the invention; and

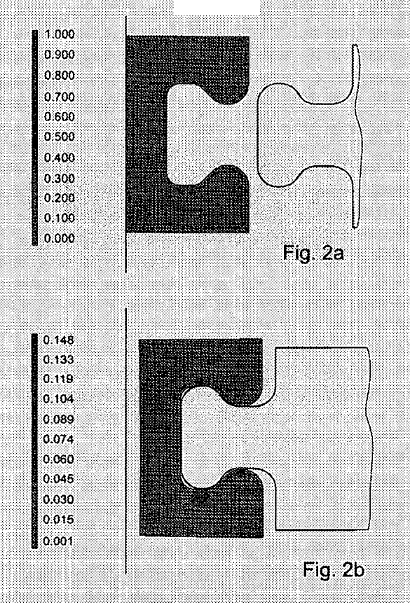

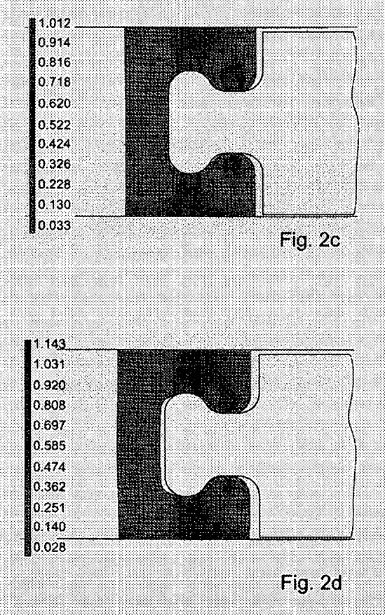

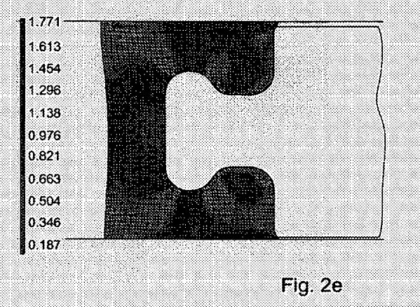

FIG. 2 a series of results of FEM-simulations showing stresses in radial cross sections of the shaped-seal of the invention for different situations, namely

FIG. 2a an uninstalled sealing element of the invention, without external forces,

FIG. 2b a sealing element mounted on the seal support body,

FIG. 2c a sealing element mounted on the seal support body and arranged in the annular gap, at room temperature and standard pressure,

FIG. 2d a sealing element mounted on the seal support body and arranged in the annular gap, at room temperature and media-side vacuum of 500 mbar absolute, and

FIG. 2e a sealing element mounted on the seal support body and arranged in the annular gap, at 150° C. and media-side high pressure of 10 bar.

The conductivity sensor illustrated in FIG. 1 includes an inner electrode 1 and an outer electrode 2, which are separated from one another, and sealed relative to one another, by a shaped-seal 3 and a seal support body 4. The inner electrode has an outer diameter of, for example, about 5 mm, and the outer electrode has, in a first axial section 22, in which the shaped-seal 3 is arranged, an inner diameter of, for example, about 14.25 mm. The electrodes have, at least in the media-contacting end section, preferably, electropolished, stainless steel surfaces having a roughness of not more than 0.4 mm.

The sealing element of the shaped-seal 3 has a radially inner, sealing surface 31, which gap-freely adjoins the inner electrode 1, and a radially outer, sealing surface 32, which gap-freely adjoins the outer electrode. The sealing surfaces are connected with one another by an essentially planar, ceiling surface 33. The ceiling surface 33 limits the measuring chamber of the conductivity sensor in the axial direction. In a base surface 34 lying opposite to the ceiling surface, a cavity 36 widening into the interior of the sealing element is provided. The sealing element is composed of a perfluoropolymer, especially EPDM.

The seal support body has an essentially cylindrical base section, which is bounded by an annular end face 42 facing the shaped-seal 3. From the end face 43, an anchoring ring 44 extends in the axial direction, with the anchoring ring having a cross section complementary to the cavity 36 and engaging in such shape-interlockedly, in order to hold the shaped-seal 3 in position.

The seal support body 4 is composed of a shape-retaining, insulating material, for example, PEEK. The seal support body 4 has in the base section 41 in an axial section of its inner, lateral surface a screw thread, into which the inner electrode 1 is screwed, after the mounting of the shaped-seal 3 on the seal support body 4. The outer electrode 2 has on its inner wall a second axial section 24, which borders on the first axial section 22, and its diameter steadily decreases in the direction toward the first axial section, i.e., the second axial section 24 extends conically. For assembly, a preinstalled assembly composed of the inner electrode 1, the seal support body 4 and the shaped-seal 3 is introduced into an end section of the second electrode 2 away from the media-side end section of the second electrode 2, with the shaped-seal 3 experiencing a defined radial compression as it passes through the second axial section 24 of the second electrode 2.

As evident in FIGS. 2a to e, the sealing arrangement of the invention is usable under the most varied of situations, without that a failure is to be feared. In the diagrams, increasing stresses are indicated by darker grayscales.

FIG. 2a shows the uninstalled, shaped-seal stress-free, with the anchoring ring still separated from the shaped-seal.

FIG. 2b shows the shaped-seal on the anchoring ring, wherein to be observed are, on the one hand, the radial widening of the shaped-seal, and, on the other hand, the moderate stress peaks at the points of maximum width of the anchoring ring.

FIGS. 2c to e show the shaped-seal 3 radially clamped in the annular gap at various conditions of pressure and temperature. Observable are, first of all, that no intolerable stress peaks occur, second, the sealing surfaces are always completely contacted, and third, the shaped-seal 3 is not pulled off the anchoring ring 44.

Thus, the sealing arrangement of the invention achieves the object of providing an improved sealing ring, which is suitable, especially, for hygienic applications in the face of strong pressure fluctuations.

1-16. (canceled)

17. A shaped-seal for sealing an annular gap between an outer peripheral wall and an inner peripheral wall against a medium, comprising:
an elastic, radially clampable, annular sealing element having:
an annular, radially outer, sealing surface for contacting the outer peripheral wall;
an annular, radially inner, sealing surface for contacting the inner peripheral wall;
an annular, media-side, ceiling surface, which extends between said radially outer, sealing surface and said radially inner, sealing surface;
an annular base surface, which extends on a side facing away from said ceiling surface between said radially outer sealing surface and said radially inner sealing surface; and
at least one annular cavity in said annular base surface for accommodating an anchoring ring, said cavity has at least one undercut.

18. The shaped-seal as claimed in claim 17, wherein:
said sealing element has in an uninstalled state, in equilibrium, a cross section of, for instance, approximately rectangular, outer contour.

19. The shaped-seal as claimed in claim 17, wherein:
said at least one cavity is arranged in the cross section, to a first approximation, symmetrically to said sealing element.

20. The shaped-seal as claimed in claim 17, wherein:
said cavity has rounded contours in its cross section.

21. The shaped-seal as claimed in claim 20, wherein:
concave surfaces of said sealing element within said cavity have a minimum radius of curvature of not less than 5%, and preferably not less than 8%, of the width of the cross sectional contour of said sealing element.

22. The shaped-seal as claimed in claim 17, wherein:
the surface of said sealing element in the interior of said cavity has a concave region, which transitions toward the opening in said base surface into a convex region;
and such transition is a point of inflection or a section with constant slope, and the constant slope or the slope at the point of inflection is not less than 30°, preferably not less than 38° and further preferably not less than 42°.

23. The shaped-seal as claimed in claim 17, wherein:
the surface of said sealing element in the interior of said cavity has a concave region, which transitions toward the opening in said base surface into a convex region; and
this transition is a point of inflection or a section with constant slope, and the slope at the point of inflection is not more than 60°, preferably not more than 52° and further preferably not more than 48°.

24. The shaped-seal as claimed in claim 17, wherein:
said sealing element comprises an elastomer, especially a perfluoroelastomer, EPDM or Kalrez perfluoroelastomer.

25. A sealing arrangement, comprising a shaped-seal as claimed in claim 17, as well as a seal support body having an annular base section and an anchoring ring arranged on an end face of said base section.

26. The sealing arrangement as claimed in claim 25, wherein:
said anchoring ring engages shape-interlockedly in undercuts of said cavity of said sealing element.

27. The sealing arrangement as claimed in claim 25, wherein:
said anchoring ring is so dimensioned, that the cross section of said sealing element is widened, when said cavity is arranged about said anchoring ring.

28. The sealing arrangement as claimed in claim 25, wherein:
radial compression of said sealing element amounts, for instance, to 10% to 25%, when the sealing arrangement is arranged in an annular gap.

29. The sealing arrangement as claimed in claim 25, wherein:
said seal support body comprises a shape-retaining material, for example, PEEK.

30. The sealing arrangement as claimed in claim 25, wherein:
for preventing excessive relative movement between the shaped-seal and abutting sealing surfaces, an inner wall or an outer wall of said seal support body is fixedly connected with one or both of the walls.

31. A sensor for registering a physical or chemical process parameter, comprising a sealing arrangement as claimed in claim 25, wherein:
a first sensor component forms the inner wall of an annular chamber and a second, coaxially arranged, sensor component the outer wall of the annular chamber;
and the sensor components are electrically insulated from, and centered relative to, one another by the sealing arrangement.

32. A conductivity sensor, comprising a sealing arrangement as claimed in claim 25, wherein:
a first metal electrode forms the inner wall of an annular chamber and a second, coaxially arranged, electrode the outer wall of the annular chamber; and
said two electrodes are electrically insulated from, and centered relative to, one another by the sealing arrangement.
